(19) United States
(12) Patent Application Publication
(10) Pub. No.: US 2010/0252828 A1
(43) Pub. Date: Oct. 7, 2010

(54) SEMICONDUCTOR DEVICE COMPRISING A CHIP INTERNAL ELECTRICAL TEST STRUCTURE ALLOWING ELECTRICAL MEASUREMENTS DURING THE FABRICATION PROCESS

(76) Inventors: Michael Grillberger, Radebeul (DE); Matthias Lehr, Dresden (DE)

Correspondence Address: WILLIAMS, MORGAN & AMERSON, 10333 RICHMOND, SUITE 1100, HOUSTON, TX, 77042, US

(21) Appl. No.: 12/417,749

(22) Filed: Apr. 3, 2009

(51) Int. Cl. H01L 23/00; H01L 21/66; H01L 21/768

(52) U.S. Cl. 257/48; 438/18; 438/622; 257/E23.002; 257/E21.531; 257/E21.575

(57) ABSTRACT

A test structure or a circuit element acting temporarily as a test structure may be provided within the die region of sophisticated semiconductor devices, while probe pads may be located in the frame in order to not unduly consume valuable die area. The electrical connection between the test structure and the probe pads may be established by a conductive path including a buried portion, which extends from the die region into the frame below a die seal, thereby maintaining the electrical and mechanical characteristics of the die seal. Hence, enhanced availability of electrical measurement data and superior authenticity of the data may be accomplished, wherein the measurement data may be obtained during the production process.

### BACKGROUND OF THE INVENTION

1. Field of the Invention

Generally, the present disclosure relates to the field of fabricating integrated circuits, and, more particularly, to the monitoring of electrical measurement data of semiconductor devices on the basis of corresponding electrical test structures.

2. Description of the Related Art

Today's global market forces manufacturers of mass products to offer high quality products at a low price. It is thus important to improve yield and process efficiency to minimize production costs. This holds especially true in the field of semiconductor fabrication, since, here, it is essential to combine cutting-edge technology with mass production techniques. It is, therefore, the goal of semiconductor manufacturers to reduce the consumption of raw materials and consumables while at the same time improve process tool utilization, since, in modern semiconductor facilities, equipment is required which is extremely cost-intensive and represents the dominant part of the total production costs. Consequently, high tool utilization, in combination with a high product yield, i.e., with a high ratio of good devices to faulty devices, results in increased profitability.

Integrated circuits are typically manufactured in automated or semi-automated facilities, thereby passing through a large number of process and metrology steps to complete the devices. The number and the type of process steps and metrology steps a semiconductor device has to go through depends on the specifics of the semiconductor device to be fabricated. A usual process flow for an integrated circuit may include a plurality of photolithography steps to image a circuit pattern for a specific device layer into a resist layer, which is subsequently patterned to form a resist mask used in further processes for forming device features in the device layer under consideration by, for example, etch, implantation, deposition, polish and anneal processes and the like. Thus, layer after layer, a plurality of process steps are performed based on a specific lithographic mask set for the various layers of the specified device. For instance, a sophisticated CPU requires several hundred process steps, each of which has to be carried out within specified process margins so as to fulfill the specifications for the device under consideration. Since many of these processes are very critical, a plurality of metrology steps have to be performed to efficiently monitor and control the process flow. Typical metrology processes may include the measurement of layer thickness, the determination of dimensions of critical features, such as the gate length of transistors, the measurement of dopant profiles, the number, the size and the type of defects, electrical characteristics, such as the transistor drive current, the threshold voltage thereof, i.e., the voltage at which a conductive channel forms in the channel region of a field effect transistor, the transconductance, i.e., the change of drive current with gate voltage, and the like. As the majority of the process margins are device-specific, many of the metrology processes and the actual manufacturing processes are specifically designed for the device under consideration and require specific parameter settings at the adequate metrology and process tools.

In a semiconductor facility, a plurality of different product types are usually manufactured at the same time, such as memory chips of different design and storage capacity, CPUs of different design and operating speed and the like, wherein the number of different product types may even reach a hundred and more in production lines for manufacturing ASICs (application specific ICs). Since each of the different product types may require a specific process flow, different mask sets for the lithography, specific settings in the various process tools, such as deposition tools, etch tools, implantation tools, chemical mechanical polishing (CMP) tools, metrology tools and the like, may be necessary. Consequently, a plurality of different tool parameter settings and product types may be encountered simultaneously in a manufacturing environment, thereby also creating a huge amount of measurement data, since typically the measurement data are categorized in accordance with the product types, process flow specifics and the like.

Thus, a large number of different process recipes, even for the same type of process tools, may be required which have to be applied to the process tools at the time the corresponding product types are to be processed in the respective tools. However, the sequence of process recipes performed in process and metrology tools, or in functionally combined equipment groups, as well as the recipes themselves, may have to be frequently altered due to fast product changes and highly variable processes involved. As a consequence, the tool performance in terms of throughput and yield are very critical manufacturing parameters as they significantly affect the overall production costs of the individual devices. Therefore, great efforts are made to monitor the process flow in the semiconductor facility with respect to yield-affecting processes or process sequences in order to reduce undue processing of defective devices and to identify flaws in process flows and process tools. For example, at many stages of the production process, inspection steps are implemented for monitoring the status of the devices. Moreover, other measurement data may be generated for controlling various processes, in which the measurement data may be used as feed forward and/or feedback data.

The measurement data for controlling production processes, such as lithography processes and the like, may be obtained by dedicated structures, which may be positioned within the die region if a corresponding area consumption of these structures may be compatible with the overall design criteria of the circuit layout under consideration. In other cases, the test structures may typically be provided in an area outside of the actual die region, which may also be referred to as a frame, which may be used for dicing the substrate when separating the individual die regions. During the complex manufacturing sequence for completing semiconductor devices, such as CPUs and the like, an immense amount of measurement data may be created, for instance by inspection tools and the like, due to the large number of complex manufacturing processes, the mutual dependencies of which may be difficult to assess, so that, usually, factory targets may be established for certain processes or sequences, which are assumed to provide process windows to obtain a desired degree of final electrical behavior of the completed devices. That is, the complex individual processes or related sequences may be monitored and controlled on the basis of respective inline measurement data such that the corresponding process results may be maintained within specified process margins, which in turn may be determined on the basis of the final electrical performance of the product under consideration. Consequently, in view of enhanced overall process control and appropriately targeting the various processes on the basis of the final electrical performance, electrical measurement data may be created on the basis of dedicated test structures that may be provided in the frame region in combination with appropriate probe pads formed in the metallization system at a very advanced manufacturing stage. These electrical test structures may comprise appropriate circuit elements, such as transistors, conductive lines, capacitors and the like, which may be appropriately connected to the probe pads so as to allow dedicated measurement strategies for assessing electrical performance of the various circuit elements in the test structure, which may then be related to the performance of the circuit elements in the actual die region. These electrical measurement data may include resistance values of conductive structures, threshold voltages of transistors, drive current capability of the transistors, leakage currents and the like, wherein these electrical characteristics may be influenced by the large number of manufacturing processes involved. Since these electrical measurement data may be obtained at a very late stage of the overall manufacturing process, a significant delay with respect to the actual manufacturing processes in which the corresponding test structures have been formed typically exists, thereby requiring sophisticated predictive process control strategies in order to take into consideration the significant delay, which may even be in the range of several weeks for typical semiconductor production environments. Additionally, the significant delay in providing the corresponding electrical measurement data may thus contribute to a high probability of producing a large number of products with less desirable performance characteristics, if a factory disturbance may occur in the time period between the critical manufacturing processes and the delivery of associated electrical measurement data.

With reference to FIGS. 1a-1b, a semiconductor device including an electrical test structure will now be described to explain in more detail certain problems which may be accompanied with conventional manufacturing and process control strategies on the basis of conventionally formed electrical test structures.

FIG. 1a schematically illustrates a top view of a semiconductor device 100 which comprises a die region 110, which is to be understood as an area of the semiconductor device 100 in which circuit elements and an associated metallization system is to be formed in accordance with design criteria so as to establish a functional integrated circuit having a specified electrical behavior. Consequently, the term die region is to be understood to include any materials, such as substrate materials, semiconductor regions, insulating materials and metals and the like, as may be required for providing a desired functional behavior within a specified area. It should be appreciated that during most of the manufacturing sequence for forming the semiconductor device 100, a plurality of die regions 110 may be defined on an appropriate substrate, such as a semiconductor wafer and the like, wherein the number of individual die regions 110 depends on the size of the die region under consideration and the size of the substrate. The die region is typically defined on the basis of a border provided between two adjacent die regions, wherein the corresponding border may typically comprise a frame or frame region 130, which may represent a region in which dicing of the carrier material may be performed in a very advanced manufacturing stage prior to packaging the individual die regions 110. Consequently, a lateral size of the frame region 130 may typically be selected so as to provide a respective process margin during dicing of the carrier material while on the other hand not unduly consuming valuable space on the carrier material. Moreover, in complex semiconductor devices, a die seal 120 is provided, which may separate the actual die region 110 from the frame 130 and may provide electrical and mechanical integrity of the die region 110. That is, the die seal 120 may typically be formed in the metallization system of the semiconductor device 100 so as to substantially continuously enclose the die region 110, thereby providing a “wall” of metal, such as copper, which may therefore represent a barrier with respect to mechanical defects, which may, for instance, be caused in the sensitive dielectric materials of the metallization system, for instance during handling of the device 100 and in particular during dicing of the semiconductor devices 100 in the frame region 130 when separating the individual die regions 110.

As previously explained, electrical measurement data may have to be obtained from the semiconductor device 100 in order to assess an expected electrical performance of circuitry located within the die region 110. For this purpose, one or more electrical test structures 140 may be positioned in the frame region 130 in combination with respective probe pads 141A, 141B which are appropriately dimensioned so as to be accessible by external electrical probes in order to obtain the desired electrical measurement data. That is, the probe pads 141A, 141B may require an appropriate size for being contacted by external probes, while the number of the respective probe pads may depend on the configuration of corresponding features of the structure 140. For instance, if a simple two-point measurement may have to be performed on the basis of the test structure 140, two probe pads 141A, 141B may be sufficient, while, in other cases, three or more probe pads may have to be provided in order to obtain the desired information. It should also be appreciated that a plurality of electrical test structures 140 in combination with associated probe pads may be provided within the region 130. It should further be noted that an area 142, comprising respective test features in relation to the size of the probe pads 141A, 141B, is not to scale, since typically the required area for the test features 142 may be significantly less compared to the area consumed by the probe pads 141A, 141B. Thus, by positioning the test structure 140 in the frame region 130, valuable chip area within the die region 110 may not be wasted.

FIG. 1b schematically illustrates a cross-sectional view of a portion of the semiconductor device 100 along the section Ib, as indicated in FIG. 1a. As illustrated, the semiconductor device 100 comprises a substrate 101, which may represent any appropriate carrier material, such as a semiconductor material, a dielectric material and the like, above which is formed a semiconductor layer 102, for instance in the form of a silicon-based layer and the like. In and above the semiconductor layer 102, a plurality of circuit elements 151 may be formed within the die region 110, wherein the circuit elements 151 may thus represent the semiconductor elements required for obtaining the desired functional circuit to be established within the die region 110. Furthermore, the test features 142, for instance in the form of circuit elements having the same or a similar configuration as the circuit elements 151, may be provided in the frame 130 in and above the semiconductor layer 102. For example, the test structure 140 may comprise one or more transistor elements, the characteristics of which may be assessed in order to determine the electrical performance of the circuit elements 151 in the die region 110. The semiconductor layer 102 in combination with any component formed above the layer 102, such as gate electrode structures for the circuit elements 151, when provided in the form of transistor elements, may define a device level 150 in the die region 110 and also in the frame region 130. The circuit elements in the device level 150 and similarly the test features 142 may be enclosed and passivated by a contact layer 170, which may be comprised of any appropriate dielectric material, such as silicon nitride, silicon dioxide and the like, in which respective contact elements 171A, 171B and 171C may be formed in order to provide an electrical connection from the device level 150 to a metallization system 160, in which the overall electrical “wiring” for the circuit elements 151 in the device level 150 and for the test features 142 may be established, since typically the required electrical connection for the circuit architecture under consideration may not be established within the device level 150. For example, the contact elements 171A may represent respective contact elements within the die region 110, while contact elements 171B may represent the contact elements connecting the die seal 120 with the device level, wherein the contact element 171B may be provided in the form of a substantially continuous metal-containing region. Similarly, the contact elements 171C may establish the electrical connection between the test features 142 and the metallization system 160 in the frame region 130.

The metallization system 160 may comprise a plurality of metallization layers 160A, 160B, 160C, depending on the overall complexity of the semiconductor device 100. Each of the metallization layers 160A, 160B, 160C within the die region 110 and the frame region 130 may comprise metal lines 161 and/or vias 162 which may electrically connect two adjacent metallization layers. On the other hand, the die seal 120 may comprise “metal lines” 161 instead of the vias 162, thereby providing a substantially continuous metal wall surrounding the die region 110. Furthermore, as illustrated in FIG. 1b, the uppermost metallization layer 160C may comprise the probe pads 141A, 141B electrically connected to the test features 142 via the metallization layers in the frame region 130.

Typically, the semiconductor device 100 as illustrated in FIGS. 1a and 1b may be formed on the basis of the following processes. First, the circuit elements 151 and the test features 142 may be formed in the device level 150 on the basis of respective manufacturing sequences, as previously described, which may involve complex lithography steps, deposition processes, implantation processes, anneal techniques, etch processes, CMP processes and the like. For example, gate dielectric materials and gate electrode materials may be formed by sophisticated oxidation and/or deposition techniques, followed by advanced lithography and patterning processes, thereby determining the respective critical dimensions, such as a gate length of transistor elements and the like. In principle, the same processes may also be applied in the frame region 130 in order to form the test features 142, the characteristics of which may be used for assessing the characteristics of the actual circuit elements 151 in the die region 110. However, with the continuous shrinkage of device dimensions, the manufacturing processes involved may be highly sensitive with respect to pattern density and the like. For instance, etch processes may have a different etch rate in an area where a plurality of densely spaced features are to be formed compared to other areas in which corresponding features may be provided with moderately great distances. Similarly, the deposition of material layers may also suffer from a moderate dependence on pattern density. Consequently, a certain non-uniformity with respect to layer thickness and thus resulting surface topography may be observed at various device regions, which may also have a significant influence on critical lithography steps, for instance steps for forming gate electrodes and the like. Consequently, even after a regular planarization of the resulting surface topography, different height levels may be created, in particular in the die region 110 relative to the frame region 130, in which the global and local neighborhood of the test features 142 may be very different compared to the die region 110. Thus, the final electrical behavior of the test features 142 may differ from the electrical performance of the circuit elements 151, in particular for sophisticated semiconductor devices comprising highly scaled circuit elements. For example, a gate length of transistor elements may be in the range of 50 nm and less, so that even very subtle differences in surface topography between the region 110 and the frame region 130 may result in a significant difference of electrical characteristics. Consequently, it may become increasingly difficult to actually assess the characteristics of the circuit elements 151 on the basis of the test features 142.

After completing the device level, the contact layer 170 may be formed followed by appropriate manufacturing sequences for forming the metallization system 160, for instance using well-established inlaid techniques on the basis of copper, low-k dielectric materials and the like. It should be appreciated that also, in these device levels, discrepancies between the die region 110 and the frame region 130 may occur, for instance due to critical lithography steps, in combination with a different surface topography caused by etching, deposition, planarization and the like, as previously explained. Hence, respective test structures including metal features to be evaluated on the basis of a corresponding test structure may also provide different performance characteristics compared to actual metal features in the die region 110. Thus, when electrical measurement data may be obtained from the semiconductor device 100 so as to actually process the active circuitry in the die region 110, the probe pads 141A, 141B may be accessed by respective probes of an external measurement device in order to establish a respective current flow through the test features 142, the electrical response of which may then be detected and assessed. Thus, due to the above-described differences of, for instance, critical dimensions and the like, which may be caused by a different surface topography and the like, the electrical measurement data may not properly represent the actual electrical performance of the circuit elements 151, which may thus result in an inappropriate targeting of complex manufacturing processes, such as lithography steps and the like, which may finally result in a deteriorated yield distribution since products of inferior quality may be increasingly produced.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to semiconductor devices and methods in which electrical measurement data may be obtained with increased correlation with respect to electrical performance of circuit elements of the active circuitry by placing the corresponding test structure in the die region of the semiconductor device. On the other hand, a significant consumption of die area may be avoided by positioning respective probe pads in the frame region and connecting the test structure with the probe pads on the basis of an appropriately designed conductive path. In some illustrative aspects disclosed herein, the conductive path may at least partially be provided below a metallization system of the semiconductor device, thereby enabling the “crossing” of a die seal formed in the metallization system of the semiconductor device, without unduly affecting the mechanical characteristics thereof. Consequently, a high degree of flexibility in selecting an appropriate position for the test structure may be provided so that very similar conditions during the fabrication of the test features may be established, thereby resulting in high correlation between the electrical performance of the test features and the actual circuit elements. In other cases, at least a portion of the test features represent actual circuit elements, which may, at least temporarily, act as test features which may be accessible in the manufacturing process via the conductive path and the probe pads, which may be established at any appropriate manufacturing stage, for instance in the device level and/or in any of the metallization layers still to be formed. Consequently, electrical measurement data may be available at any desired stage of the manufacturing process with a high degree of significance with respect to the actual electrical performance of the active circuitry under consideration. In some illustrative aspects disclosed herein, the buried portion of the conductive path may be established within any appropriate device level below the metallization system, for instance in the active semiconductor layer, the substrate, above the semiconductor layer or the contact level, substantially without negatively affecting the integrity of the die seal within the metallization system.

One illustrative semiconductor device disclosed herein comprises a die region comprising a metallization system and a semiconductor region formed above a substrate. The semiconductor device further comprises a plurality of circuit elements formed in and above the semiconductor region. Furthermore, a die seal region is formed in the metallization system and a conductive path connected to the plurality of circuit elements is provided and comprises a buried portion formed below a part of the die seal region.

One illustrative method disclosed herein comprises forming a plurality of circuit elements in and above a semiconductor region, wherein the plurality of circuit elements are formed within a die region of a semiconductor device. The method further comprises forming a buried conductive path connecting to at least one of the plurality of circuit elements. Finally, the method comprises forming a metallization system above the plurality of circuit elements and the buried conductive path, wherein the metallization system comprises a die seal region separating the die region from a frame region and wherein a portion of the die seal region is formed above the buried conductive path.

A further illustrative method disclosed herein comprises providing at least one circuit element in a die region of a semiconductor device, wherein the die region is separated from a frame region by a die seal region. The method additionally comprises providing a conductive path connecting the at least one circuit element with one or more probe pads formed in the frame region. Finally, the method comprises obtaining electrical measurement data from the at least one circuit element by connecting the one or more probe pads with a measurement device.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate a top view and a cross-sectional view, respectively, of a semiconductor device comprising an electrical test structure positioned in a frame of the semiconductor device to obtain electrical measurement data on the basis of a conventional strategy;

FIG. 2a schematically illustrates a top view of a semiconductor device including a plurality of circuit elements within a die region, at least one of which may be used as a test feature connected to probe pads located in the frame region via a conductive path comprising a buried portion, according to illustrative embodiments;

FIG. 2b schematically illustrates a cross-sectional view of the semiconductor device of FIG. 2a according to illustrative embodiments in which a buried conductive path is formed below a die seal region in the semiconductor layer of the device;

FIG. 2c schematically illustrates a cross-sectional view of the semiconductor device of FIG. 2a wherein the buried portion may be provided in the form of a “gate electrode structure,” according to still further illustrative embodiments;

FIG. 2d schematically illustrates a cross-sectional view of the semiconductor device of FIG. 2a in which the buried portion may be established in the contact level, according to illustrative embodiments;

FIG. 2e schematically illustrates a top view of a transistor active region and a buried portion of the conductive path for connecting to probe pads external to the die region, according to illustrative embodiments;

FIGS. 2f-2g schematically illustrate cross-sectional views of the device of FIG. 2e during various manufacturing stages in providing a buried portion as a low resistance path on the basis of a sequence for forming drain and source regions of transistors, according to illustrative embodiments; and

FIGS. 2h-2i schematically illustrates cross-sectional views of the semiconductor device during various manufacturing stages in providing the buried portion in a substrate material of an SOI configuration, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides semiconductor devices and methods for forming and operating the same in which the correlation between electrical measurement data and the electrical performance of circuit elements of the active circuitry within a die region may be enhanced. For this purpose, electrical measurement data may be obtained at any appropriate manufacturing stage from within the die region, for instance by regular circuit elements which may temporarily be used as test features and/or by dedicated test structures, wherein the electrical access may be accomplished via a conductive path including a buried portion so as to not unduly affect the mechanical integrity of a die seal region. Consequently, a minimal die area may be provided for providing test features or for establishing an appropriate interconnect scheme for temporarily using actual circuit elements as test features, while the appropriately dimensioned probe pads may be provided in the frame region. Consequently, depending on the interconnect scheme for connecting the circuit elements acting as test features with the probe pads, die internal measurement data may be available at relatively early manufacturing stages compared to conventional strategies since the buried portion of the conductive path may provide the potential for accessing the device level within the die region, as soon as respective probe pads may be formed and thus available in the frame region, which may even allow the generation of electrical measurement data prior to actually forming respective metallization layers. On the other hand, during the manufacturing sequence for providing the die seal in the metallization system, well-established concepts may be used, thereby maintaining a high degree of compatibility while also providing the desired mechanical integrity of the metallization system, for instance with respect to the creation of cracks during the handling of the sensitive metallization system and the dicing of the carrier material. In some illustrative embodiments, the electrical connection of the die seal region with the active semiconductor layer or the substrate may be maintained, since only a respective part of the die seal that corresponds to the buried conductive path may be electrically insulated from the device level so as to maintain electrical insulation between the probe pads and the die seal region. Consequently, substantially identical electrical and mechanical characteristics for the die seal region may be achieved relative to conventional strategies, while nevertheless providing superior electrical measurement data, which may also be gathered at any appropriate manufacturing stage.

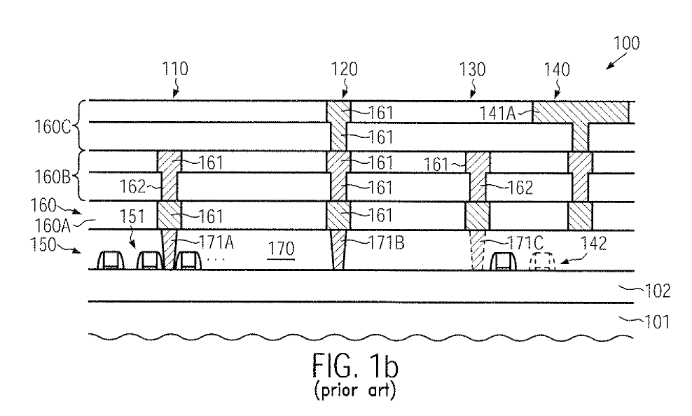

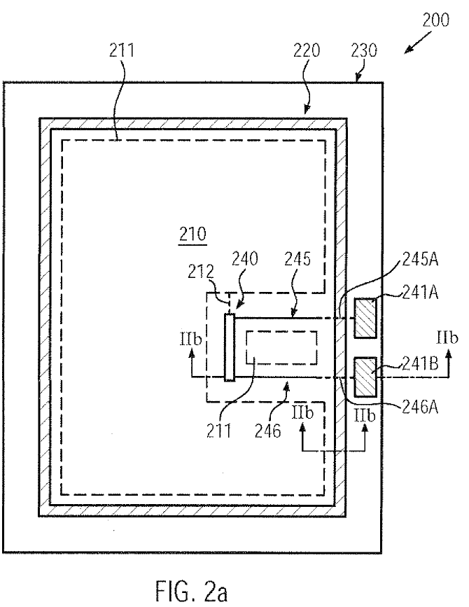

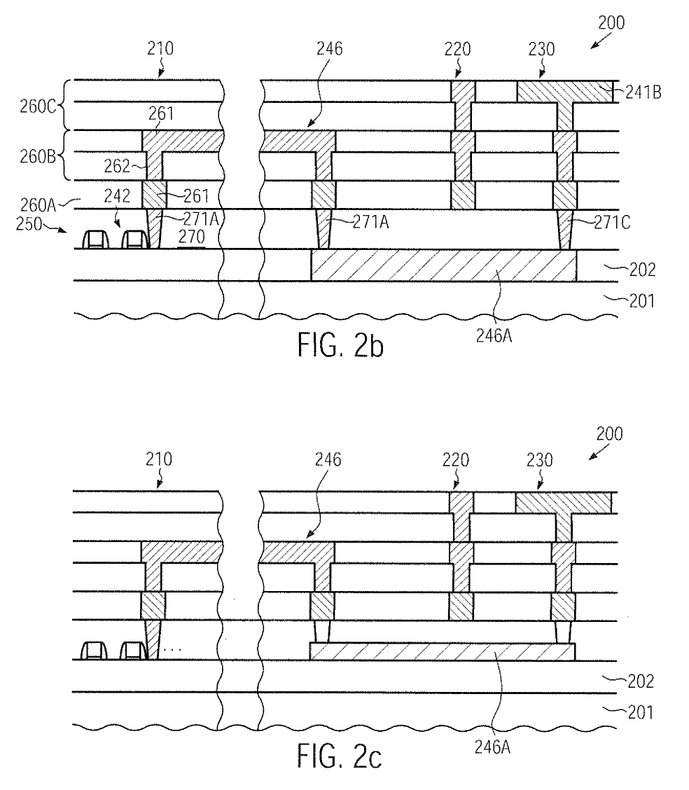

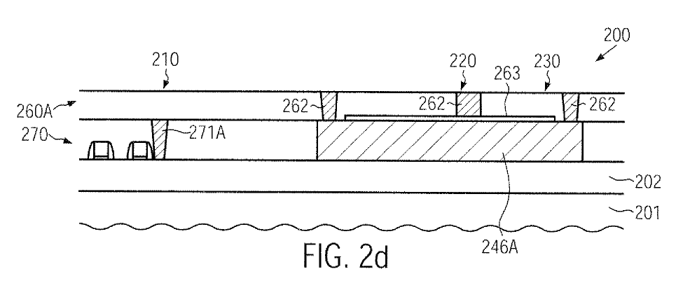

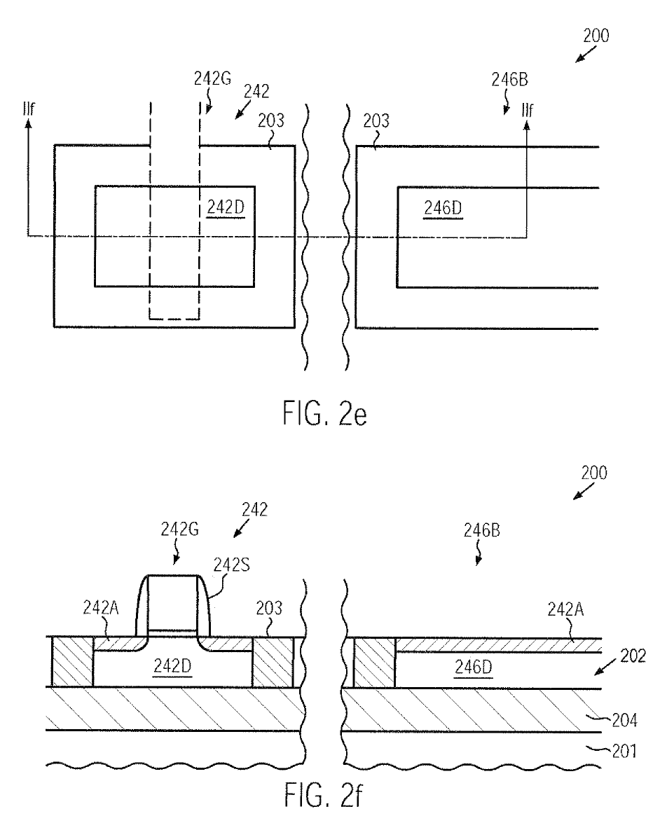

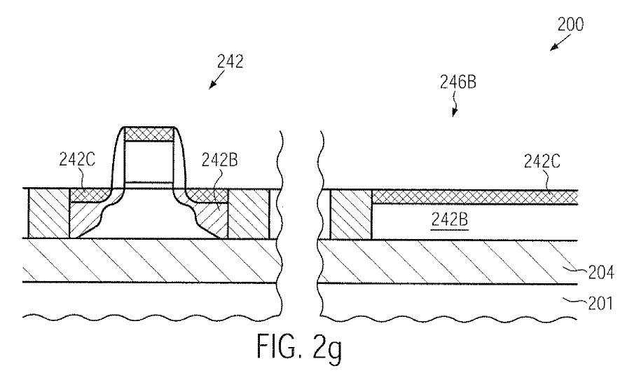

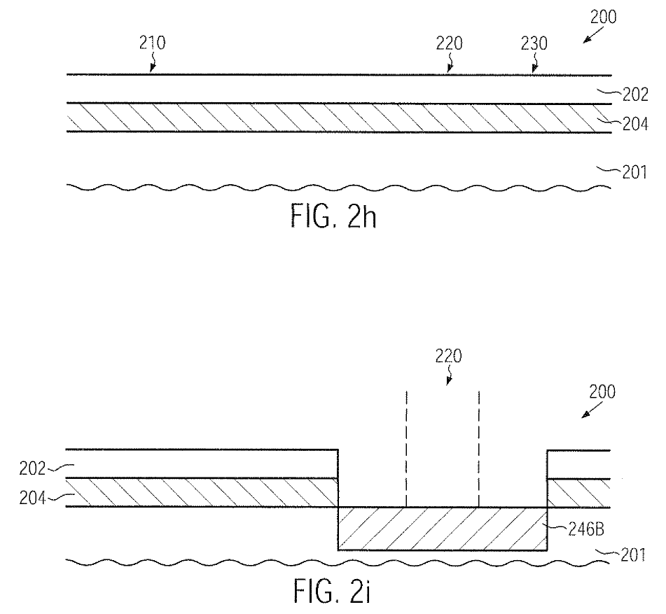

FIG. 2a schematically illustrates a top view of a semiconductor device 200 comprising a die region 210, a die seal region 220, laterally enclosing the die region 210, and a frame region 230. Furthermore, the die region 210 may comprise a functional circuit 211, which may provide the desired electrical functions according to the overall circuit design. For example, the functional circuit 211 may comprise digital circuitry, analog circuitry and the like, low power circuitry, high power circuitry, possibly in combination, when complex systems on a chip are considered. For example, CPUs including memory areas, ASICs including a combination of complex digital and analog circuitry and the like may be provided within the die region 210. Furthermore, a circuit portion 240 may be provided within the die region 210 and may represent, in some illustrative embodiments, a dedicated test structure configured to provide electrical measurement data with respect to at least one electrical characteristic, such as transistor characteristics, in the form of threshold voltage, drive current, switching speed and the like. In this case, the circuit portion 240 in the form of a test structure may represent at least one circuit element that is electrically isolated from the functional circuit 211 and may therefore be operated without affecting the circuit 211. In other illustrative embodiments, the circuit portion 240 may comprise at least one or more circuit elements which may represent a part of the functional circuit 211, for instance by providing an appropriate interconnect system between the circuit portion 240 and one or more parts of the functional circuit 211. In this case, in addition to the interconnect structure 212, an interconnect structure may be provided that enables the dedicated use of the at least one or more circuit elements as test features to obtain die internal electrical measurement data. For this purpose, one or more conductive paths 245, 246 may be provided so as to connect to the circuit portion 240, irrespective of whether this may represent a dedicated test structure or a part of the circuit 211, which may temporarily be used as a test structure. The conductive paths 245, 246 may be established, at least partially, within a device level, a contact level and a metallization system, depending on the overall circuit configuration. Furthermore, the conductive paths 245, 246 may each comprise a “buried” portion or section 245A, 246A, respectively. The portions 245A, 246A may be considered as buried sections in the sense that the portions 245A, 246A may extend from the die region 210 to the frame region 230 below the die seal 220, i.e., below the metallization system of the device 200, as will be explained later on in more detail. Consequently, by means of the conductive paths 245, 246, the circuit portion 240, representing, at least temporarily, a test structure, may be connected to a plurality of probe pads 241A, 241B, which are appropriately dimensioned to enable external access by test equipment, for instance any appropriate test device, as is well known in the art.

Consequently, due to the arrangement of the semiconductor device 200, electrical measurement data may be obtained by die internal devices, such as the circuit portion 240, without unduly consuming valuable chip area since the area consuming probe pads 241A, 241B may be positioned in the frame region 230. Furthermore, the mechanical integrity of the die seal region 220, which may be formed by connected metal lines in the metallization system of the device 200, may be maintained, while nevertheless allowing electrical access of the circuit portion 240 via the probe pads 241A, 241B and the conductive paths 245, 246. Thus, during the manufacturing phase of the semiconductor device 200, electrical measurement data may be gathered from the circuit portion 240 as soon as the probe pads 241A, 241B are formed. For instance, if the conductive paths 245, 246 are substantially established within one or more lower-lying metallization levels, the probe pads 241A, 241B may be formed at an early manufacturing stage and may thus enable electrical access of the circuit portion 240 in order to obtain the desired die internal measurement data. In some illustrative embodiments, the conductive paths 245, 246 may even be established within the device level, possibly in combination with the contact level of the device 200, substantially without requiring any overlying metallization layer, so that valuable electrical measurement data may be obtained at or even prior to completing the basic transistor structures. Since the circuit portion 240 may be formed on the basis of a similar neighborhood as is encountered for actual circuit elements of the functional circuit 211, or if the circuit portion 240 may represent a part of the circuit 211, the corresponding electrical measurement data may have a high degree of authenticity in order to evaluate the electrical performance of the functional circuit 211, which may also result in a superior control strategy, for instance with respect to appropriately determining target values for critical processes, as previously explained.

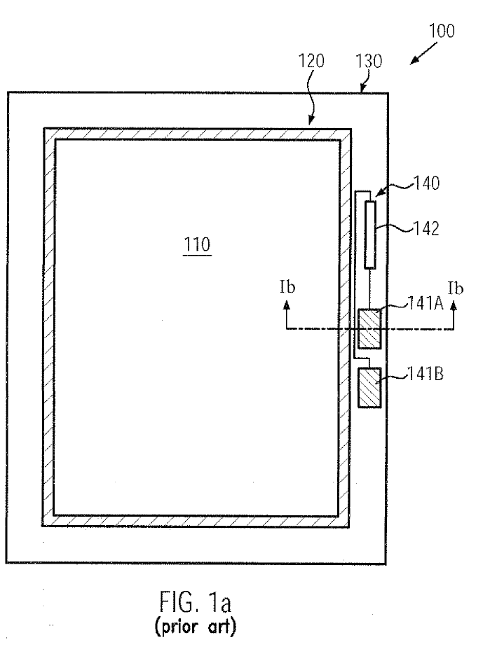

FIG. 2b schematically illustrates a cross-sectional view of the semiconductor device 200 along the section IIb according to illustrative embodiments. As illustrated, the semiconductor device 200 may comprise a substrate 201, above which may be formed a semiconductor layer 202. With respect to the substrate 201 and the semiconductor layer 202, the same criteria apply as previously explained with reference to the device 100. Furthermore, in and above the semiconductor layer 202, circuit elements may be formed as required for the functional circuit 211 and the circuit portion 240. For convenience, a plurality of circuit elements 242 are shown in FIG. 2b, which may represent circuit elements of the circuit portion 240, at least one of which may be used, at least temporarily, as a test feature to obtain electrical measurement data from within the die region 210. The semiconductor layer 202 and the circuit elements formed therein and thereon may define a device level of the semiconductor device 200, as also previously explained. Furthermore, a metallization system 260 may be provided, which may comprise a plurality of metallization layers 260A, 260B, 260C, as required by the wiring scheme of the functional circuit 211. It should be appreciated that, in the manufacturing stage shown, the metallization system 260 may not yet be completed, when highly complex semiconductor devices are considered. Thus, the metallization system 260, when completed, may comprise more metallization layers as shown in FIG. 2b. In other cases, as previously explained, the metallization system 260 may comprise a lesser number of metallization layers if the corresponding conductive paths 246, 245 may be established with a reduced number of metallization layers so that corresponding electrical measurement data may be obtained at an earlier stage of the entire manufacturing sequence. In the embodiment shown, the conductive path 246 may be established by the metallization layer 260A using a metal line 261, which is connected to a further metal line 261 in the metallization layer 260B by means of a via 262. Furthermore, the conductive path 246 may be connected to one or more of the circuit elements 242 via a contact level 270, which may comprise an appropriate dielectric material and respective contact elements 271A within the die region 210 and contact elements 271C in the frame region 230. It should be appreciated that the die seal region 220 may not be connected to the device level 250 by means of the contact level 270 within a portion that may at least correspond to the buried conductive path 246A, while in other areas in which the buried portions 246A, 245A are not provided, a corresponding contact element or region may be provided, as is also previously explained with reference to the device 100 when referring to the contact portions 171B (FIG. 1b). Consequently, the buried conductive path 246A is connected to the circuit portion 240, i.e., one or more of the circuit elements 242, by the contact elements 271 and the metal lines 261 and vias 262 within the die region 210 and is connected to the probe pad 241B by means of the contact element 271C and metal line 261 and vias 262 positioned in the frame region 230. Consequently, an electrical connection of the circuit portion 240 to the probe pad 241B may be established by means of the conductive path 246, wherein the buried portion 246A provides mechanical integrity of the die seal region 220 while also preserving electrical isolation from the die seal region 220 by providing the dielectric material of the contact level 270, at least above the buried portion 245, without contact elements connecting to the die seal region 220.

The semiconductor 200 as shown in FIG. 2b may be formed on the basis of the following processes. The circuit elements for the functional circuit 211 in combination with the circuit elements 242 of the circuit portion 240 may be formed in accordance with a desired manufacturing technique, wherein a high degree of similarity of process conditions may be established, since the circuit portion 240 may be positioned at any appropriate location within the die region 210 so as to obtain similar process conditions and thus electrical performance of the circuit elements 242 with respect to other critical areas within the die region 210. For example, if it is known that certain critical processes, such as lithography, planarization techniques and the like, may be highly sensitive to pattern density, the circuit elements 242 may be provided at device regions in which a similar local neighborhood may be provided for the circuit elements 242 so that a comparable process result will be obtained at critical device areas and for the circuit elements 242. During the manufacturing sequence for forming the circuit elements 242, the buried portion 246A may also be formed, for instance by any appropriate manufacturing techniques, such as implanting a dopant species in order to provide a low resistance path and the like. Respective manufacturing processes in which the buried portion 246A may be formed on the basis of a sequence for forming a transistor active region will be described later on in more detail. Thus, if desired, a high degree of compatibility with conventional process techniques may be maintained, thereby not unduly contributing to additional process complexity. Thereafter, the contact level 270 may be formed, for instance by depositing appropriate dielectric materials, followed by a patterning process for defining contact holes for the contact elements 271A, 271C and respective contact elements or portions for the die seal region 220 laterally outside of the buried conductive path 246A. Consequently, an appropriate lithography mask may be provided so as to avoid electrical contact between the die seal region 220 and the buried portion 246A. Thereafter, metal may be filled into the contact openings in accordance with well-established process techniques. Next, the metallization system 260, or at least a portion required for completing the conductive path 246 and providing the probe pads 241A, 241B may be formed in accordance with well-established process techniques, wherein, however, contrary to the conventional strategies, an appropriate design may be used for providing the metal lines 261 and vias 262 so as to connect to the buried portion 246A and to the probe pads 241A, 241B. Thus, after completing the conductive path 246, electrical measurement data may be obtained by connecting the probe pads 241A, 241B with external electrical test equipment. Thereafter, any further metallization levels may be provided, if required.

It should be appreciated that respective test features may also be provided within the metallization system 260 within the die region 210, which may also be connected by an appropriate conductive path including a buried portion, such as the portions 246A, 245A, when the testing of metal features is desired. Furthermore, when electrical measurement data may be obtained from the circuit portion 240 at a later manufacturing stage, respective probe pads may be provided so as to overlay the previously formed pads 241A, 241B, thereby enabling external access at any further advanced manufacturing stage during the formation of the metallization system 260.

FIG. 2c schematically illustrates a cross-sectional view of the semiconductor device 200 according to further illustrative embodiments in which the buried portions 245A, 246A may be provided above the semiconductor layer 202, for instance in the form of a gate electrode material. As illustrated, the buried portion 246A may be formed on or above the semiconductor layer 202 or may be formed on or above an isolation region provided in the semiconductor layer 202, depending on the overall process strategy. For this purpose, in some illustrative embodiments, the buried portion 246A may be formed along gate electrode structures of transistors in a common manufacturing sequence. For example, upon forming a gate dielectric material and a gate electrode material on the semiconductor layer 202 in transistor active regions and also above isolation regions, such as trench isolations and the like, a subsequent patterning process may be performed on the basis of an appropriately designed lithography mask so as to also pattern the buried portion 246A. Typically, gate electrode structures may be provided with a moderately low resistivity, for instance by incorporating a moderately high dopant concentration and/or providing a metal-containing material, for instance in the form of a metal silicide, so that the buried portion 246A may also comprise a moderately low resistance so as to act as an interconnect structure between the circuit portion 240 and the probe pads 241A, 241B. In other cases, sophisticated gate electrode materials in the form of metal-containing materials may be used, possibly in process strategies using high-k dielectric gate materials, and also a corresponding process sequence may be applied for the buried portion 246A. Consequently, the conductive path 246 may be established without additional process steps so that a high degree of compatibility with conventional process strategies may be maintained.

FIG. 2d schematically illustrates the semiconductor device 200 according to further illustrative embodiments, in which the buried portion 246A, 245A may be provided in the contact level 270. In the manufacturing stage shown in FIG. 2d, the first metallization layer 260A may be formed above the contact level 270 and may comprise respective metal lines 262 so as to connect to the buried portion 246A, which may be provided in the form of a contact “element” within the contact level 270. Similarly, in the die seal region 220, a respective metal line 262 may be provided which, however, may be electrically isolated from the buried portion 246A by an additional etch stop layer 263, for instance in the form of silicon nitride and the like, which may additionally be provided at least above the buried portion 246A so as to maintain electrical integrity of the conductive path 246 still to be established via the subsequent metallization layers 260B, as is also previously explained with reference to FIGS. 2b-2c. Consequently, the contact level 270 may be formed on the basis of well-established process techniques, wherein, however, a different contact mask may be used to form a respective contact hole corresponding to the buried portion 246A in the dielectric material of the contact level 270. Thereafter, the contact element 271A in the die region 210 may be formed commonly with the buried portion 246A and possibly with other contact portions connecting to the die seal region, i.e., the metal line 262 at areas outside of the buried portion 246A. Thereafter, the layer 263 may be deposited, for instance in the form of silicon dioxide, silicon nitride and the like, depending on the type of material to be deposited for the metallization layer 260A. Next, the etch stop material may be patterned so as to obtain portion 263, as illustrated in FIG. 2d, and thereafter the usual deposition sequence for providing an appropriate dielectric material for the metallization layer 260A may be performed. Thereafter, the further processing may be continued according to well-established strategies, wherein, however, during the patterning of the dielectric material of the metallization layer 260A, the additional etch stop layer 263 may reliably avoid contact to the buried portion 246A. Consequently, also in this case, a highly conductive connection may be established while maintaining a high degree of process compatibility while only requiring an additional deposition and patterning step.

With reference to FIGS. 2e-2g, further illustrative embodiments will now be described, in which a highly conductive buried portion may be formed during a standard manufacturing sequence for forming drain and source regions of transistors of a specific conductivity type.

FIG. 2e schematically illustrates a top view of portions of the semiconductor device 200 wherein, for convenience, one of the circuit elements 242 in the form of a transistor element is shown and a part of the buried portion 246 located within the die region 210 is illustrated. In the manufacturing stage shown, an active region 242D for the transistor 242 may be defined on the basis of an isolation structure 203, which may be provided in the form of a shallow trench isolation. Furthermore, a gate electrode 242G, indicated as dashed lines, is to be formed above the active region 242D and a portion of the isolation structure 203. Similarly, in the manufacturing stage shown, the buried portion 246B may comprise an active region 246D, laterally enclosed by the isolation structure 203. It should be appreciated that an active region is to be understood as a semiconductor region in which an appropriate dopant concentration, possibly in combination with metal-containing materials, is to be established in order to provide a desired conductivity.

FIG. 2f schematically illustrates the device 200 according to the section IIf of FIG. 2e. In the embodiment shown, the device 200 may represent an SOI configuration in which a buried insulating layer 204 may be provided between the semiconductor layer 202, including the isolation structures 203, and the substrate 201. It should be appreciated, however, that the principles disclosed herein may also be applied to a bulk configuration, i.e., a configuration in which the buried insulating layer 204 may be omitted, at least at certain device regions of the device 200. Thus, as illustrated, the gate electrode structure 242G may be formed above the active region 242D, which is laterally enclosed by the isolation structures 203. Furthermore, an implant region 242A may be formed in the active region 242D so as to provide a desired dopant concentration for drain and source extension regions of the transistor 242. Similarly, in the buried portion 246B, the implantation region 242A may be formed in an upper portion of the active region 246D.

The device 200 as shown in FIG. 2f may be formed on the basis of well-established process techniques, including the formation of a gate dielectric material followed by the deposition of an appropriate gate electrode material, such as polysilicon and the like, which may then be patterned to obtain the gate electrode structure 242G. Thereafter, an appropriate implantation sequence may be performed to obtain the doped region 242A in the active region 242D while using the gate electrode structure 242G as an implantation mask. Similarly, a doped region 242A may be formed in the active region 246D of the buried portion 246B. Thereafter, a spacer structure 242S is formed on sidewalls of the gate electrode structure 242G in accordance with well-established process techniques. It should be appreciated that, during the implantation process for forming the regions 242A, other transistor types may be masked in accordance with well-established CMOS techniques.

FIG. 2g schematically illustrates the semiconductor device 200 in a further advanced manufacturing stage. As illustrated, deep drain and source regions 242B may be formed in the transistor 242 and a similar dopant concentration 242B may also be provided in the buried portion 246B. Furthermore, metal silicide regions 242C may be formed on the drain and source regions as well as in the gate electrode of the transistor 242 and a corresponding metal silicide region 242C may also be provided in an upper portion of the buried conductive path 246B. Consequently, the buried portion 246B may be provided as a low resistance path due to the high dopant concentration 242B and the metal silicide region 242C, which may be formed along with a respective transistor structure, such as the transistor 242, thereby substantially not contributing to additional process complexity. Furthermore, in the SOI configuration shown in FIG. 2g, the isolation structures 203 may provide a lateral insulation of the buried portion 246B, while the buried insulating layer 204 may also provide for a vertical insulation so that, in combination with dielectric material from the contact level 270 (not shown in FIG. 2g), a substantially complete electrical insulation of the buried portion 246B may be obtained, except for any contact elements 271A, 271C for connecting to the metallization system, as previously explained.

With reference to FIGS. 2h-2i, further illustrative embodiments will now be described in which the buried portion 246A, 246B may be formed additionally or alternatively to the device level 250 and/or the contact level 270 within the substrate 201.

FIG. 2h schematically illustrates the device 200 in an earlier manufacturing stage. As illustrated, the semiconductor layer 202 may be formed on the buried insulating layer 204, thereby defining an SOI configuration. As is well-known, in many complex integrated circuits comprising an SOI configuration, at least in some device areas, circuit elements may also be incorporated into the substrate 201, for instance in the form of substrate diodes and the like, which may frequently be used for thermal sensing applications and the like. For this purpose, an opening may be formed through the semiconductor layer 202 and the buried insulating layer 204 so as to expose a portion of the substrate 201. Consequently, during a respective process sequence or during a separate process sequence, an appropriate opening may also be formed at an area corresponding to the die seal 220 in order to provide a buried portion in the substrate 201. For this purpose, in combination with a corresponding manufacturing sequence for forming substrate diodes or in a separate sequence, an appropriate etch mask may be provided to expose a desired portion of the semiconductor layer 202, while masking other device areas. Thereafter, an etch sequence may be performed on the basis of well-established etch recipes so as to etch through the semiconductor layer 202 and the buried insulating layer 204.

FIG. 2i schematically illustrates the device 200 after the completion of the above-described process sequence. Moreover, the buried portion 246B may be formed in the substrate 201, for instance on the basis of any appropriate technique, such as providing a high dopant concentration, possibly in combination with a metal silicide region, when the portion 246B may be formed in accordance with a transistor manufacturing sequence, as is previously explained with reference to FIGS. 2f-2g, however, in the substrate material 201. For example, during a corresponding process sequence, respective substrate diode structures may also be formed, thereby also providing a high degree of process compatibility with conventional strategies. Thereafter, the further processing may be continued in a similar manner as previously described, i.e., the contact level 270 and the metallization system 260 may be formed, as previously described, so as to complete the conductive path 246 including the buried portion 246B.

As a result, the present disclosure provides semiconductor devices and methods of forming and operating the same, wherein die internal measurement data may be obtained, for instance via a dedicated test structure or via circuit elements which may temporarily be used as test features, which may be accomplished on the basis of an appropriately designed interconnect structure in the form of one or more conductive paths, each of which may comprise a buried portion which provides a connection from the die region to the frame region, without affecting the mechanical integrity of the die seal region. That is, the buried portion may extend from the die region into the frame region below the die seal, thereby maintaining mechanical stability of the semiconductor device, while nevertheless providing a low resistance path for connecting die internal circuit elements with probe pads located in the frame region. The die seal may nevertheless remain in electrical contact with the substrate or any portions outside of the buried conductive path, thereby also providing substantially the same electrical performance of the die seal compared to conventional devices. Consequently, the circuit features used for obtaining electrical measurement data may be formed with a high degree of authenticity with respect to critical device features in the die region, thereby enhancing the evaluation of the electrical performance of the active circuitry in the die region. Furthermore, since at least the conductive bridge between the die region and the frame region may be established in an early manufacturing stage, the present disclosure provides the possibility of obtaining electrical measurement data at an early manufacturing stage, that is, as soon as the conductive path between the circuit elements acting as test features and the probe pads may be established. Consequently, electrical measurement data of superior significance may be obtained during the manufacturing sequence, i.e., for instance prior to completing the metallization system, without compromising the electrical and mechanical function of the die seal.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a die region comprising a metallization system and a semiconductor region formed above a substrate;
a plurality of circuit elements formed in and above said semiconductor region;
a die seal region formed in said metallization system; and
a conductive path connected to said plurality of circuit elements and comprising a buried portion formed below a part of said die seal region.

2. The semiconductor device of claim 1, wherein said plurality of circuit elements define a test structure configured to provide electrical measurement data independently from a functional circuit formed in said die region.

3. The semiconductor device of claim 1, wherein at least some of said plurality of circuit elements represent a part of a functional circuit formed in said die region.

4. The semiconductor device of claim 1, further comprising a frame region enclosing said die seal region, wherein said frame region comprises at least one probe pad electrically connected to said buried portion of said conductive path.

5. The semiconductor device of claim 1, wherein said buried portion is at least partially formed in said semiconductor region.

6. The semiconductor device of claim 1, wherein said buried portion is at least partially formed in said substrate.

7. The semiconductor device of claim 1, wherein said buried portion is at least partially formed above a height level defined by a surface of said semiconductor region.

8. The semiconductor device of claim 7, wherein said buried portion comprises a gate electrode material.

9. The semiconductor device of claim 7, wherein said buried portion is at least partially formed in a contact level of said semiconductor device.

10. The semiconductor device of claim 1, wherein said die seal region is formed in each metallization layer of said metallization system.

11. The semiconductor device of claim 10, wherein said die seal region is electrically connected to at least one of said semiconductor region and said substrate via a contact level of said semiconductor device.

12. The semiconductor device of claim 11, wherein said die seal region is electrically insulated from said conductive path.

13. A method, comprising:
forming a plurality of circuit elements in and above a semiconductor region within a die region of a semiconductor device;
forming a buried conductive path connecting to at least one of said plurality of circuit elements; and
forming a metallization system above said plurality of circuit elements and said buried conductive path, said metallization system comprising a die seal region separating said die region from a frame region, a portion of said die seal region being formed above said buried conductive path.

14. The method of claim 13, further comprising forming a test structure in and above said semiconductor region within said die region, wherein said test structure comprises said at least one circuit element.

15. The method of claim 13, wherein forming said metallization system further comprises forming at least one probe pad in said frame region that is electrically connected to said buried conductive path.

16. The method of claim 15, wherein forming said metallization system further comprises forming a first interconnect structure in said metallization system within said die region wherein said first interconnect structure connects to said test structure and said buried conductive path, wherein forming said metallization system further comprises forming a second interconnect structure in said metallization system within said frame region wherein said second interconnect structure connects to said buried conductive path and said at least one probe pad.

17. The method of claim 13, wherein said buried conductive path is formed in a process sequence for forming drain and source regions of one type of transistor.

18. The method of claim 13, wherein said buried conductive path is formed in a process sequence for forming gate electrode structures of transistor devices.

19. The method of claim 13, wherein said buried conductive path is formed in a process sequence for forming circuit elements in said substrate.

20. The method of claim 14, further comprising connecting said at least one probe pad with an external measurement probe and obtaining electrical measurement data from said test structure.

21. A method, comprising:
providing at least one circuit element in a die region of a semiconductor device, said die region being separated from a frame region by a die seal region;
providing a conductive path connecting said at least one circuit element with one or more probe pads formed in said frame region; and
obtaining electrical measurement data from said at least one circuit element by connecting said one or more probe pads with a measurement device.

22. The method of claim 21, wherein providing said conductive path comprises providing a buried portion in said conductive path that crosses said die seal region below a metallization system of said semiconductor device.

23. The method of claim 21, wherein said electrical measurement data is obtained prior to completing a metallization system of said semiconductor device.

24. The method of claim 21, wherein said at least one circuit element is electrically isolated from other circuit elements so as to form a test structure that is functionally separated from a functional circuitry formed by said other circuit elements.

25. The method of claim 21, wherein obtaining said electrical measurement data comprises providing said at least one circuit element as a part of a functional circuit comprising further circuit elements and temporarily using said at least one circuit element as a test feature.
